(19) United States
(12) Patent Application Publication
(10) Pub. No.: US 2019/0115935 A1
(43) Pub. Date: Apr. 18, 2019

(54) Forward Error Correction and Asymmetric Encoding for Video Data Transmission Over Multimedia Link

(71) Applicant: Lattice Semiconductor Corporation, Portland, OR (US)

(72) Inventors: Sergey Yarygin, San Jose, CA (US); Gyudong KIM, Sunnyvale, CA (US); Laurence A. Thompson, Morgan Hill, CA (US); Kihong Kim, San Jose, CA (US); Chandlee B. Harrell, Los Altos, CA (US)

(73) Assignee: Lattice Semiconductor Corporation, Portland, OR (US)

(21) Appl. No.: 16/090,165

(22) PCT Filed: Apr. 3, 2017
(86) PCT No.: PCT/US2017/025762

§ 371 Date: Sep. 28, 2018

Related U.S. Application Data
(60) Provisional application No. 62/318,082, filed on Apr. 4, 2016.

(51) Int. Cl. H03M 13/11; H04L 1/00; H04N 21/2383; H04N 21/4363

(52) U.S. Cl. CPC H03M 13/1162; H03M 13/1145; H04L 1/0042; H04L 2001/0096; H04N 21/43635; H04L 1/0057; H04N 21/2383

(57) ABSTRACT

A source device includes a forward error correction encoder circuit to generate error correction protected blocks from video data packets. Each error correction protected block includes data words and error correction words. An encoder circuit encode X-bit words of the error correction protected blocks into Y-bit encoded words for transmission to a sink device over one or more multimedia lanes of a multimedia communication link, where X is smaller than Y.

### BACKGROUND

### Field of the Disclosure

This disclosure pertains in general to data communications, and more specifically to forward error correction and asymmetric encoding for video data transmission over multimedia interfaces.

### Description of the Related Art

Different types of multimedia data are often transmitted from a source device to a sink device over an interface link, such as an HDMI link. Conventional encoding and transmission methods are sometimes unable to handle high-speed transmission of high resolution video in a reliable manner. For example, 4K video, which has roughly four times the resolution of 1080p video and a higher color depth can lead to a large increase in I/O speed requirements.

### SUMMARY

An embodiment of the present disclosure is related to forward error correction and asymmetric encoding of video data packets for transmission over multimedia lanes of a multimedia communication link, e.g., a data interface cable or multimedia cable, such as an HDMI cable. In one embodiment, a source device includes a forward error correction encoder circuit to generate error correction protected blocks from video data packets. Each error correction protected block includes data words and error correction words. An encoder circuit encodes X-bit words of the error correction protected blocks into Y-bit encoded words for transmission to a sink device over one or more multimedia lanes of a multimedia communication link, where X is smaller than Y.

In one embodiment, the source device includes a packetizer circuit to packetize video data into the video data packets. Each data packet includes an X-bit header including a P-bit type symbol and a Q-bit length symbol.

In one embodiment, the forward error correction encoder circuit generates the error correction protected blocks from the video data packets and blanking data packets. The packetizer circuit packetizes blanking data into the blanking data packets.

In one embodiment, the forward error correction encoder circuit is a Reed-Solomon forward error correction encoder.

In one embodiment, the source device of claim 1 includes a superblock aggregator circuit to aggregate the error correction protected blocks into a superblock. The encoder circuit encodes the X-bit words of the error correction protected blocks that are in the superblock. A block start word indicating a start of the superblock is transmitted across each of the multimedia lanes of the multimedia link before the Y-bit encoded words of the superblock are transmitted across the multimedia lanes.

In one embodiment, the data words of each error correction protected block each include X/2 upper bits and X/2 lower bits. The error correction words each include X/2 upper bits that are parity check bits for the X/2 upper bits of the data words, and the error correction words each include X/2 lower bits that that are parity check bits for the X/2 lower bits of the data words.

In one embodiment, the encoder circuit encodes an X-bit word into a Y-bit encoded word by encoding R lower bits of the X-bit word into S lower bits of the Y-bit encoded word. U upper bits of the X-bit word are encoded into T upper bits of the Y-bit encoded word, wherein R is different than U, R is smaller than S, and U is smaller than T.

In one embodiment, a sink device includes a decoder circuit to decode Y-bit encoded words, received from a source device over one or more multimedia lanes of a multimedia communication link, into X-bit words of error correction protected blocks, where X is smaller than Y. An error correction circuit generates data packets from the error correction protected blocks. Each error correction protected block includes data words and error correction words.

In one embodiment, the sink device includes a depacketizer circuit to depacketize the video data packets into video data. Each video data packet includes an X-bit header comprising a P-bit type symbol and a Q-bit length symbol.

In one embodiment, the error correction circuit generates blanking data packets from the error correction protected blocks. The depacketizer circuit depacketizes the blanking data packets into blanking data.

In one embodiment, the error correction circuit is a Reed-Solomon error correction decoder.

In one embodiment, the X-bit words are organized into a superblock and the start of a superblock is indicated by block start words received across each of the multimedia lanes of the multimedia communication link. The sink device further includes a superblock disaggregator circuit to disaggregate the superblock into a plurality of the error correction protected blocks.

In one embodiment, the decoder circuit decodes a Y-bit encoded word into an X-bit word of the error correction protected block by decoding S lower bits of the Y-bit encoded word into R lower bits of the X-bit word. T upper bits of the Y-bit encoded word are decoded into U upper bits of the X-bit word, wherein S is different than T, R is smaller than S, and U is smaller than T.

In one embodiment, the data words of each error correction protected block each include X/2 upper bits and X/2 lower bits. The error correction words each include X/2 upper bits that are parity check bits for the X/2 upper bits of the data words, and the error correction words each include X/2 lower bits that that are parity check bits for the X/2 lower bits of the data words.

In one embodiment, error correction protected blocks are generated from video data packets. Each error correction protected block includes data words and error correction words. X-bit words of the error correction protected blocks are encoded into Y-bit encoded words for transmission to a sink device over one or more multimedia lanes of a multimedia communication link, where X is smaller than Y.

In one embodiment, video data is packetized into the data packets. Each data packet includes an X-bit header comprising a P-bit type symbol and a Q-bit length symbol.

In one embodiment, the error correction protected blocks are generated using Reed-Solomon encoding.

In one embodiment, error correction protected blocks are aggregated into a superblock, wherein the encoding is of the X-bit words of the error correction protected blocks that are in the superblock. A block start word indicating a start of the superblock is transmitted across the multimedia lanes of the multimedia link before the Y-bit encoded words of the superblock are transmitted across the multimedia lanes.

In one embodiment, the data words of each error correction protected block each include X/2 upper bits and X/2 lower bits. The error correction words each include X/2 upper bits that are parity check bits for the X/2 upper bits of the data words, and the error correction words each include X/2 lower bits that that are parity check bits for the X/2 lower bits of the data words.

In one embodiment, the encoding of the X-bit words into Y-bit encoded words includes encoding R lower bits of the X-bit word into S lower bits of the Y-bit encoded word. U upper bits of the X-bit word are encoded into T upper bits of the Y-bit encoded word, wherein R is different than U, R is smaller than S, and U is smaller than T.

In one embodiment, Y-bit encoded words, transmitted from a source device over one or more multimedia lanes of a multimedia communication link, are decoded into X-bit words of error correction protected blocks, where X is smaller than Y. Video data packets are generated from the error correction protected blocks. Each error correction protected block includes data words and error correction words.

In one embodiment, the data packets are depacketized into video data. Each data packet includes an X-bit header comprising a P-bit type symbol and a Q-bit length symbol.

In one embodiment, the video data packets are generated from the error protected blocks using Reed-Solomon decoding.

In one embodiment, the X-bit words are organized into a superblock and the start of a superblock is indicated by block start words received across each of the multimedia lanes of the multimedia communication link. The superblock is disaggregated into the error correction protected blocks.

In one embodiment, the decoding of the Y-bit encoded words into X-bit words includes decoding S lower bits of the Y-bit encoded word into R lower bits of the X-bit word. T upper bits of the Y-bit encoded word are decoded into U upper bits of the X-bit word, wherein S is different than T, R is smaller than S, and U is smaller than T.

In one embodiment, the data words of each error correction protected block each include X/2 upper bits and X/2 lower bits. The error correction words each include X/2 upper bits that are parity check bits for the X/2 upper bits of the data words, and the error correction words each include X/2 lower bits that that are parity check bits for the X/2 lower bits of the data words.

### BRIEF DESCRIPTION OF THE DRAWINGS

The teachings of the embodiments disclosed herein can be readily understood by considering the following detailed description in conjunction with the accompanying drawings.

Figure (FIG. 1 is a high-level block diagram of a system for data communications, according to one embodiment.

FIG. 2 is a high-level block diagram of a source interface device, according to one embodiment.

FIG. 3 is a high-level block diagram of a sink interface device, according to one embodiment.

FIG. 4 is an illustration of error correction protected blocks, according to one embodiment.

FIG. 5 is a high-level block diagram of the encoding process, according to one embodiment.

FIG. 6 is a high-level block diagram of the decoding process, according to one embodiment.

FIG. 7 is an illustration of an encoded superblock, according to one embodiment.

FIG. 8 is a flow chart illustrating the operation of the source device, according to one embodiment.

### DETAILED DESCRIPTION

The Figures (FIG.) and the following description relate to various embodiments by way of illustration only. It should be noted that from the following discussion, alternative embodiments of the structures and methods disclosed herein will be readily recognized as viable alternatives that may be employed without departing from the principles discussed herein. Reference will now be made in detail to several embodiments, examples of which are illustrated in the accompanying figures. It is noted that wherever practicable similar or like reference numbers may be used in the figures and may indicate similar or like functionality.

FIG. 1 is a high-level block diagram of a system 100 for data communications, according to one embodiment. The system 100 includes a source device 110 communicating with a sink device 115 through one or more interface links 120, 150, and 180. Source device 110 transmits multimedia data streams (e.g., audio/video streams) to the sink device 115 and also exchanges control data with the sink device 115 through the interface links 120, 150, 180. In one embodiment, source device 110 and/or sink device 115 may be repeater devices.

Source device 110 includes physical communication ports 112, 142, 172 coupled to the interface links 120, 150, 180. Sink device 115 also includes physical communication ports 117, 147, 177 coupled to the interface links 120, 150, 180. Signals exchanged between the source device 110 and the sink device 115 across the interface links 120, 150, 180 pass through the physical communication ports 112, 142, and 172.

Source device 110 and sink device 115 exchange data using various protocols. In one embodiment, interface link 120 represents a High Definition Multimedia Interface (HDMI) cable. The HDMI link 120 supports differential signals transmitted via data0+ line 121, data0− line 122, data1+ line 123, data1− line 124, data2+ line 125, data2− line 126, data3+ link 127, and data3− line 128. Each differential pair of lines forms a logical communication lane that can carry one or more multimedia data streams. In other embodiments, interface link 120 (or a different interface link, such as interface links 150, 180) may contain additional differential pairs of lines that form additional logical communication lanes.

The devices 190 and 192 may be capable of communicating data over link 120 in different operating modes. For instance, the devices 190 and 192 may be capable of operating in a legacy mode (e.g., transition minimized differential signaling with 8b10b encoding) and an alternative mode (e.g., 16b18b encoding). In the legacy mode, data3+ line 127 and data3− line 128 operate as differential clock lines clock+ and clock−. In the standard mode, data3+ line 127 and data3− line 128 form a fourth logical communication lane that also is also capable of carrying one or more multimedia data streams. In standard mode, the clock signal is embedded in the signal being carried by the logical communication channels.

The HDMI link 120 may further include Consumer Electronics Control (CEC) control bus 129, Display Data Channel (DDC) bus 130, power 131, ground 132, hot plug detect (HPD) 133, and four shield lines 134 for the differential signals. In some embodiments, the sink device 115 may utilize the CEC control bus 129 for the transmission of closed loop feedback control data to source device 110.

In one embodiment, interface link 150 represents a Mobile High-Definition Link (MHL) link. The MHL link 150 supports differential signals transmitted via data0+ line 151 and data0− line 152, which form a single logical communication lane for carrying multimedia data streams. In some embodiments of MHL, there may be more than a single pair of differential data lines. In some versions of MHL, embedded common mode clocks are transmitted through the differential data lines. The MHL link 150 may further include a control bus (CBUS) 159, power 160 and ground 161. The CBUS 159 carries control data such as discovery data, configuration data and remote control commands.

The source device 110 includes a source control device 190 and the sink device 115 includes a sink control device 192. Examples of source control device 190 and sink control device 115 are integrated circuits (ICs) or other types of devices. The source control device 190 may include a transmitter that processes multimedia data streams and outputs signals for the multimedia data streams across the interface links 120, 150, 180 to the sink control device 192. The sink control device 192 may include a receiver that receives the multimedia data streams and prepares the multimedia data streams for display. The source control device 190 and sink control device 192 may also exchange and process control data across the interface links 120, 150, and 180.

In one embodiment, a representation of the source device 110, the sink device 115, or components within the source device 110 or sink device 115 may be stored as data in a non-transitory computer-readable medium (e.g., hard disk drive, flash drive, optical drive, and random access memory). These descriptions may be behavioral level, register transfer level, logic component level, transistor level, or layout geometry-level descriptions.

### Source Device

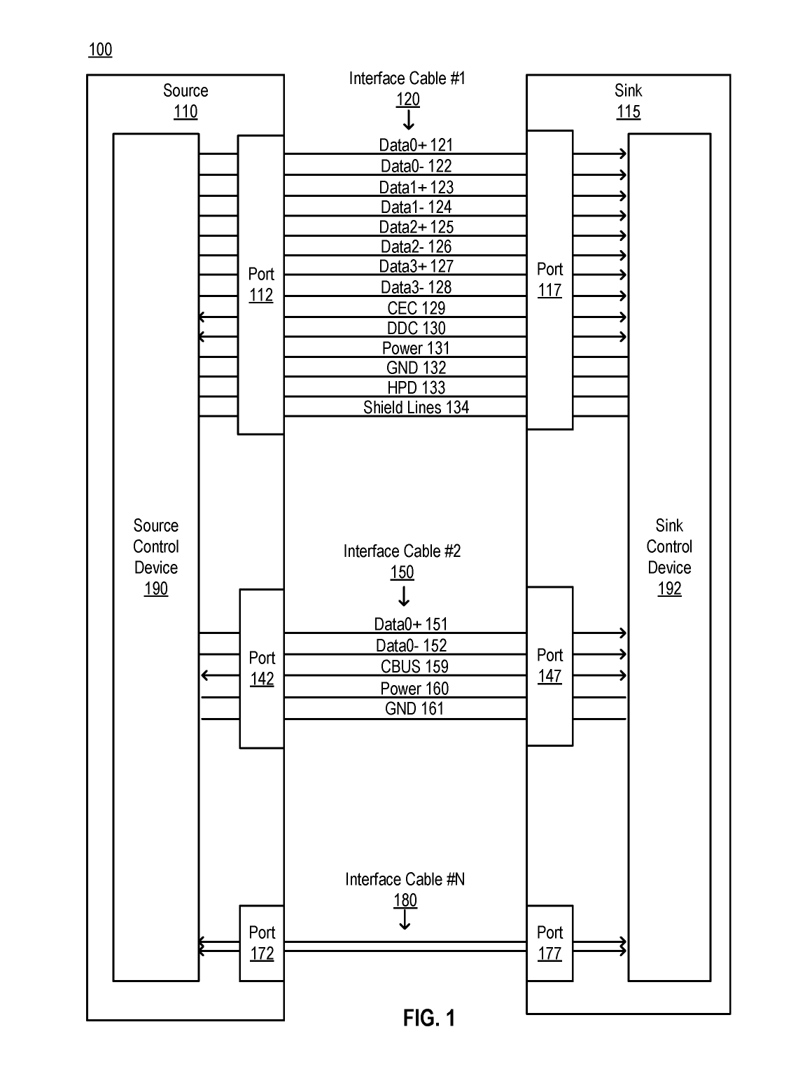

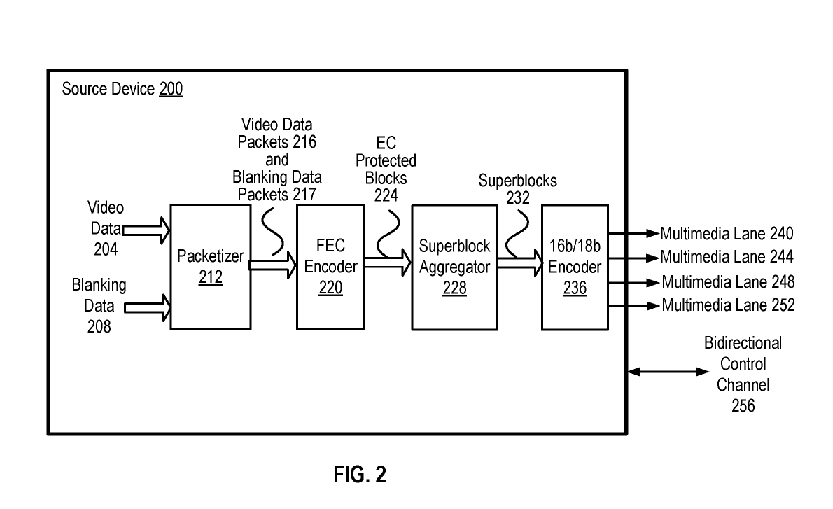

FIG. 2 is a high-level block diagram of a source device 200, according to one embodiment. The source device 200 prepares multimedia data for transmission over the multimedia lanes 240 through 252. The source device 200 includes a packetizer circuit 212, a forward error correction encoder circuit 220, a superblock aggregator circuit 228, and an encoder circuit 236. In alternative configurations, different and/or additional components may be included in the source interface device 200.

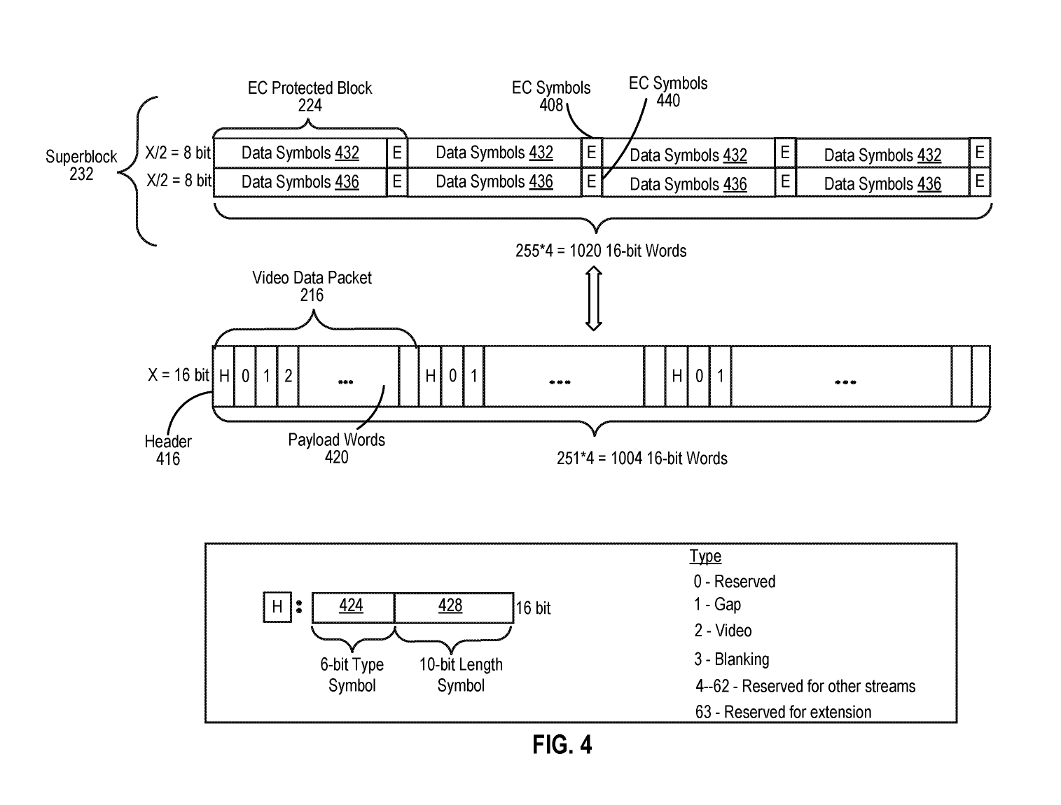

The packetizer circuit 212 packetizes the video data 204 into the video data packets 216. Each video data packet 216 includes an X-bit header comprising a P-bit type symbol and a Q-bit length symbol, as illustrated and described below with reference to FIG. 4. In one embodiment, X equals 16, P equals 6, and Q equals 10. The video data 204 may include lines of video color data in Red Green Blue (RGB) format or YCbCr format. YCbCr data can include a luma component (Y) and two chroma components (Cb and Cr).

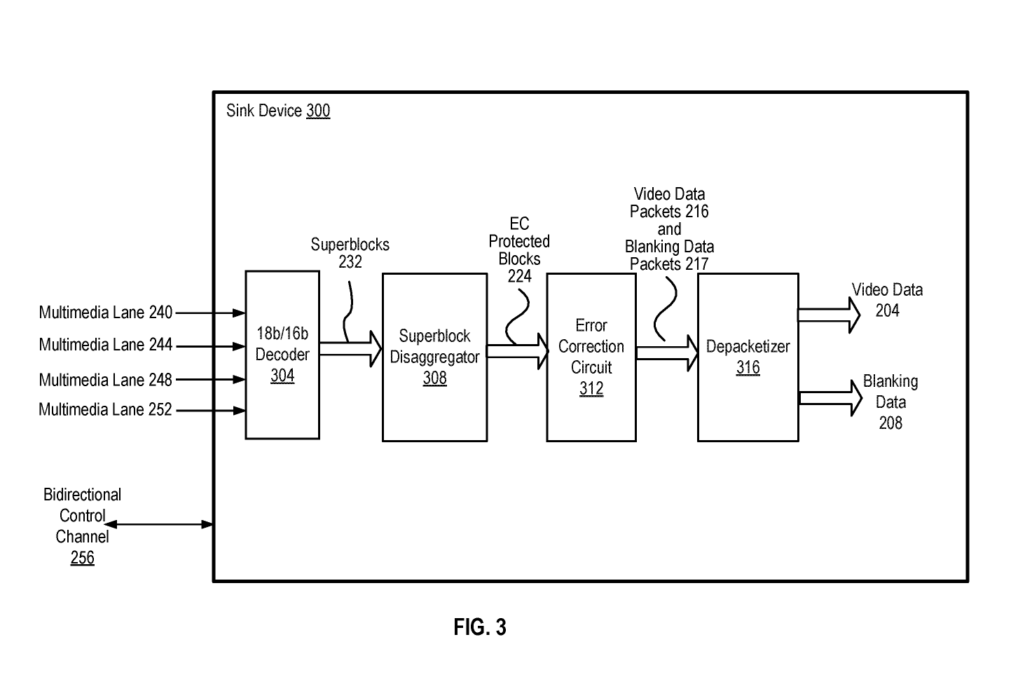

Each of the video data packets 216 is a formatted unit of video data 204 meant to be transmitted by the source device 200 over the multimedia lanes 240 through 252 to a downstream sink device, as illustrated and described in detail below with reference to FIG. 3. Each video data packet 216 includes a header and a payload, as illustrated and described in detail below with reference to FIG. 4.

Another input to the packetizer circuit 212 include the blanking period data 208. The blanking period data 208 includes audio and auxiliary data. Auxiliary data refers to metadata, i.e., information about the transmitted content. This includes information about audio and video formats (e.g., RGB, YCbCr, colorimetry, high dynamic range (HDR) metadata, content type, audio channel mapping to speakers, audio codecs, etc.). The blanking period data 208 is packetized into blanking period data packets 217. Each blanking period data packet 217 includes an X-bit header comprising a P-bit type symbol and a Q-bit length symbol, as illustrated and described below with reference to FIG. 4. In one embodiment, the structure of a video frame can include an active video period and blanking periods, such as a vertical blanking interval and horizontal blanking intervals. The video data 204 represents data from the active video period of the video frame, and the blanking period represents blanking period data from the blanking periods of the video frame. Error correction encoding and protection is therefore performed on the entire data stream including auxiliary data.

The forward error correction encoder circuit 220 generates error correction protected blocks 224 from the video data packets 216 and blanking data packets 217, and possibly other data packets. Each error correction protected block 224 includes data words and error correction words, as illustrated and described in detail below with reference to FIG. 4. Forward error correction is used to protect against errors that occur during data transmission over the multimedia lanes 240 through 252. The FEC encoder circuit 220 encodes the video data packets 216 in a redundant way by using an error-correcting code. The redundancy allows the sink device to detect errors that may occur in the transmitted video data and correct these errors without retransmission. The advantages and benefits of the method are that the sink device may correct errors without needing a reverse channel to request retransmission of data, especially when retransmissions are costly or impossible.

In one embodiment, the forward error correction encoder circuit 220 is a Reed-Solomon forward error correction encoder 220 that generates a Reed-Solomon error correcting code. The Reed-Solomon forward error correction encoder circuit 220 may be a non-binary cyclic error-correcting encoder based on univariate polynomials over finite fields. The Reed-Solomon forward error correction encoder circuit 220 can include two separate Reed Solomon encoding paths, each implementing a RS(255,251) code. Each Reed Solomon encoding path aggregates together 251 8 bit symbols from the video data packets 216 and blanking data packets 217, and then generates parity check symbols for those symbols as illustrated and described in detail below with reference to FIG. 4). In this manner, the disclosed embodiments can detect and correct erroneous video data symbols, erasures, or combinations of errors and erasures. Moreover, the Reed-Solomon forward error correction encoder circuit 220 may be used for multiple-burst bit-error correcting applications.

The data words of each error correction protected block are X bits in size. Each X bit data word includes X/2 upper bits and X/2 lower bits. The error correction words are also X bits in size. Each X bit error correction word includes X/2 upper bits that are parity check bits for the X/2 upper bits of the data words, and each X bit error correction word each includes X/2 lower bits that that are parity check bits for the X/2 lower bits of the data words, as illustrated and described in detail below with reference to FIG. 4. In one embodiment, X equals 16 and X/2 equals 8.

The superblock aggregator circuit 228 aggregates the error correction protected blocks 224 into a superblock 232, as illustrated and described in detail below with reference to FIG. 4. The encoder circuit 236 encodes the X-bit words of the error correction protected blocks 224 that are in the superblock 232 for transmission over the multimedia lanes 240 through 252. The superblock aggregator circuit 228 generates superblocks 232 having a number of words that are a multiple of a number of multimedia lanes, e.g., multimedia lanes 240 through 252 of the multimedia communication link. The superblock aggregator circuit 228 obviates padding of the error correction protected blocks 224. For example, if the number of the words in an error correction protected block 224 equals 255, and there are 4 multimedia lanes, this would results in 255÷4=63.75 words per lane. Each error correction protected block 224 would need to be padded with one additional word to results in 64 words per multimedia lane. This would results in wasted bandwidth of transmission. In this example, if the superblock aggregator circuit 228 aggregates four 255-word blocks into a superblock 232, the superblock 232 contains 255×4=1020 words. Therefore, each multimedia lane is able to transmit 1020÷4=255 encoded words between the BS symbols, which are transmitted simultaneously on all 4 lanes. A superblock 232 size of 1020 words would also work for 3 multimedia lanes since 1020÷3=340 words per lane. For multimedia links having a different number of lanes, other superblock 232 sizes may readily be determined as described above.

The encoder circuit 236 encodes X-bit words of the error correction protected blocks 224 (in superblocks 232) into Y-bit encoded words for transmission to a sink device over the multimedia lanes 240 through 252 of the multimedia communication link, where X is smaller than Y. In one embodiment, the encoder implements 16b to 18b encoding, which means that X equals 16 and Y equals 18. The resulting 18 bit words are DC balanced words that tend to avoid long strings of 0's or 1's and the encoder circuit 236 may keep one or more running disparities of 0's and 1's and use the running disparities in generating the 18-bit words.

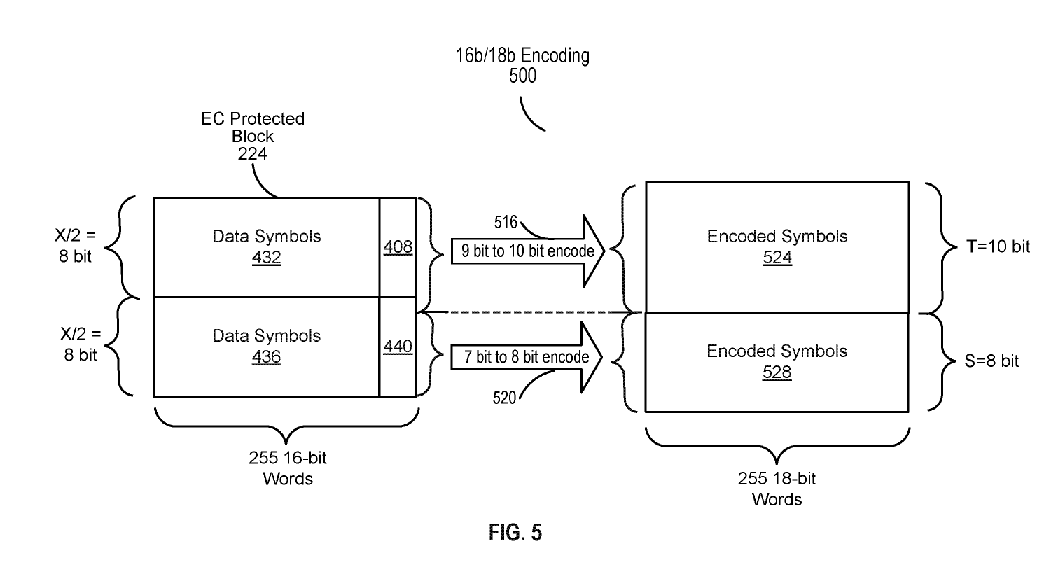

The encoder circuit 236 encodes an X bit word into a Y-bit encoded word by encoding R lower bits of the X-bit word into S lower bits of the Y-bit encoded word, where R is smaller than S, as illustrated and described in detail below with reference to FIG. 5. In one embodiment, R equals 7 and S equals 8. The encoder circuit 236 encodes U upper bits of the X-bit word into T upper bits of the Y-bit encoded word, wherein R is different than U and U is smaller than T. In one embodiment, U equals 9 and T equals 10.

During video data transmission, block start words indicating a start of a superblock 232 may be transmitted across the multimedia lanes 240 through 252 of the multimedia link before the Y-bit encoded words of the superblock 232 are transmitted across the multimedia lanes 240 through 252. In an embodiment, the block start words may be transmitted at regular intervals. In an embodiment, a block start word may be transmitted in the middle of a video period or in the middle of a blanking period. Since the video data 204 and blanking data 208 are transformed into a stream of video data packets 216 and blanking data packets 217, the block start words may be transmitted irrespective of whether the information being transmitted is video or blanking information.

The benefits and advantages of positioning the forward error correction encoder circuit 220 before the encoder circuit 236 in the datastream are that forward error correction encoding can be performed in an X-bit domain (e.g., 16-bit) instead of a larger Y-bit domain (e.g., 18-bit). This simplifies the implementation of the source device 200 because running disparity dependency issues in the encoder are reduced. In addition if the FEC encoder 220 were located after the encoder 236, the FEC encoder 220 would output parity data that would not be in the correct format for a 16b18b symbol, and these parity bits would have to be again remapped into a 16b18b symbol, thereby increasing the complexity of the encoding (and decoding) processes.

The source device 200 is connected to a sink device via a multimedia link that includes the multimedia lanes 240 through 252 and a bidirectional control channel 256. In one embodiment, the multimedia lanes 240 through 252 and the bidirectional control channel 256 may be part of an HDMI cable, such as the HDMI cable 120 illustrated and described in detail above with reference to FIG. 1. For example, multimedia lane 240 may correspond to data0+ line 121, data0− line 122, and one of the shield lines 134 of the HDMI link 120. Similarly, the other multimedia lanes 244 through 252 may correspond to the other differential pairs 123 through 128 and the other shield lines 134. The bidirectional control channel 256 may correspond to Display Data Channel (DDC) bus 130. In other embodiments, the multimedia link may include a different number of multimedia lanes. For example, the multimedia link may include a single multimedia lane, two multimedia lanes, or five multimedia lanes.

### Sink Device

FIG. 3 is a high-level block diagram of a sink device 300, according to one embodiment. The sink device 250 receives multimedia data over the multimedia lanes 240 through 252 and prepares the multimedia data for playback. The sink device 300 includes a decoder circuit 304, a superblock disaggregator circuit 308, an error correction circuit 312, and a depacketizer circuit 316. In alternative configurations, different and/or additional components may be included in the sink interface device 300.

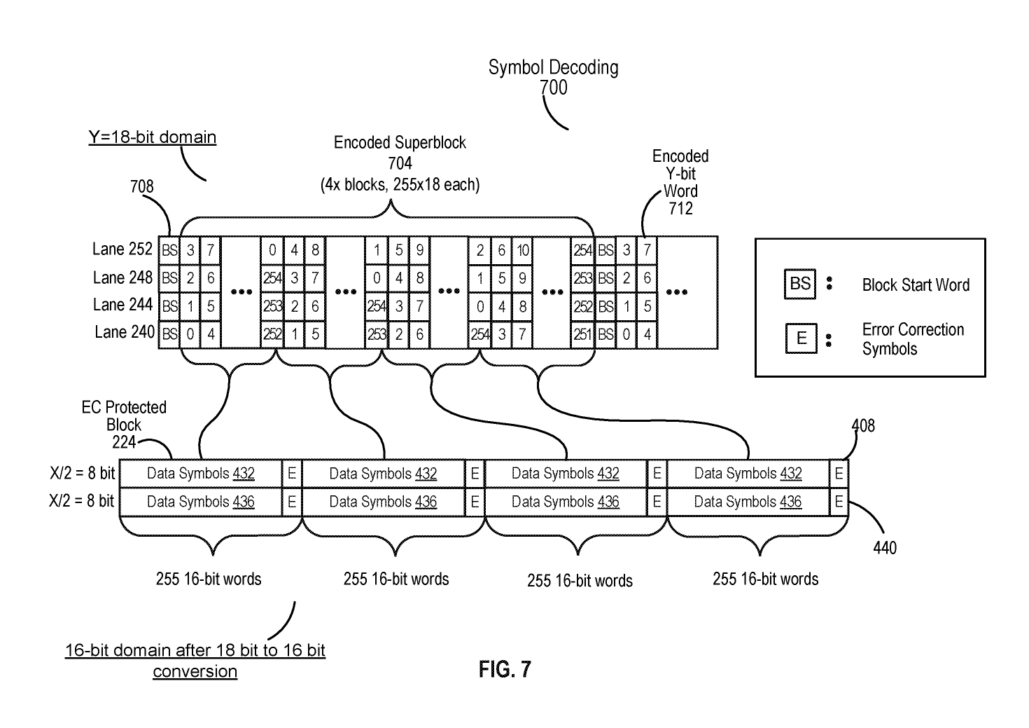

The decoder circuit 304 receives Y-bit encoded words from the source device 200 over one or more multimedia lanes 240 through 252 of a multimedia communication link. The encoded words can be organized into superblocks that are separated by block start words. Each superblock is preceded by a set of block start words indicating the start of a superblock, as illustrated and described in detail below with reference to FIG. 7.

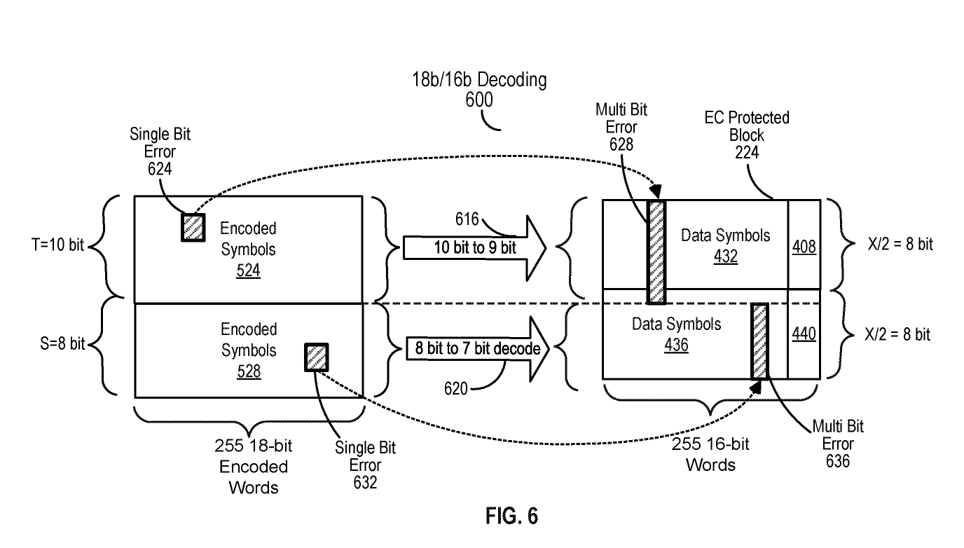

The decoder circuit 304 decodes the Y-bit words into X-bit words of error correction protected blocks 224 (in a superblock 232), where X is smaller than Y. In an embodiment, X may be 16 and Y may be 18 such that the decoder 304 implements 18b16b decoding. The decoder circuit 304 decodes a Y-bit encoded word into an X-bit word by decoding S lower bits of the Y-bit encoded word into R lower bits of the X-bit word, where R is smaller than S. In one embodiment R may be 7 and S may be 8. The decoder circuit 304 decodes T upper bits of the Y-bit encoded word into U upper bits of the X-bit word, wherein S is different than T and U is smaller than T, as illustrated and described in detail below with reference to FIG. 6. In an embodiment, U may be 9 and T may be 10.

The output of the decoder circuit 304 is a superblock 232 of decoded X-bit words representing several error correction protected blocks 224. The superblock disaggregator circuit 308 disaggregates a superblock 232 into a plurality of the error correction protected blocks 224. In other words, the superblock disaggregator circuit 308 identifies individual error correction protected blocks 224 within a superblock 232.

The error correction circuit 312 generates packets (video data packets 216 and blanking data packets 217) from the error correction protected blocks 224. In one embodiment, the depacketizer circuit 316 separates the video data packets 216 from the blanking data packets 217 for depacketizing as described below. Each error correction protected block 224 includes data words and error correction words, which include the parity check bits of the data words. The X bit data words of each error correction protected block 224 each include X/2 upper bits and X/2 lower bits, as illustrated and described below with reference to FIG. 7. The X bit error correction words each include X/2 upper bits that are parity check bits for the X/2 upper bits of the data words, and the error correction words each include X/2 lower bits that that are parity check bits for the X/2 lower bits of the data words.

The error correction circuit 312 uses the parity check bits to detect and correct errors in the data words. In one embodiment, the error correction circuit 312 compares the X-bit words in the error correction protected blocks 224 to determine whether the received binary sequence is in a known dictionary of codewords. If not in the dictionary of codewords, the error correction circuit 312 may optionally select a codeword most similar to what was received. The error correction circuit 312 may compute one or more syndrome vectors from the received data and compare this with columns of a parity check matrix to determine the presence or location of errors.

In one embodiment, the error correction circuit 312 is a Reed-Solomon error correction decoder 312 that calculates syndromes similar to parity calculation. The Reed-Solomon error correction decoder 312 may calculate syndromes that depend only on errors (not on the transmitted codewords) based on the roots of the generator polynomial. The Reed-Solomon error correction decoder 312 may locate symbol error locations by solving simultaneous equations with unknowns based on a matrix structure of Reed-Solomon codes. The Reed-Solomon error correction decoder 312 may locate symbol error locations by determining an error locator polynomial, determining the roots of the polynomial, and determining the symbol error values.

The depacketizer circuit 316 depacketizes the video data packets 216 into video data 204. The video data 204 may be RGB data for display, e.g., on a television or monitor, etc. Each video data packet 216 includes an X-bit header including a P-bit type symbol and a Q-bit length symbol, as illustrated and described below with reference to FIG. 4. In one embodiment, P equals 6 and Q equals 10. The depacketizer circuit 316 can also depacketize blanking data packets 217 into blanking data 208.

### Error Correction Protected Blocks

FIG. 4 is an illustration of error correction protected blocks 224 generated from the video data packets 216 and blanking data packets 217, according to one embodiment. Each error correction protected block 224 of X-bit words includes 2 blocks of X/2-bit symbols. In one embodiment, X may be 16, X/2 may be 8, and the error correction protected block 224 may include 255 words. Each block of X/2-bit symbols includes data symbols 432 or 436 and error correction symbols 408 or 440. Put another way, the data words of each error correction protected block 224 each include X/2 upper bits (data symbols 432) and X/2 lower bits (data symbols 436). In one embodiment, each error correction protected block 224 includes 251 data symbols 432 and 251 data symbols 436. The error correction words each include X/2 upper bits (error correction symbols 408) that are parity check bits for the X/2 upper bits (data symbols 432) of the data words. The error correction words each include X/2 lower bits (error correction symbols 440) that that are parity check bits for the X/2 lower bits (data symbols 436) of the X-bit data words. In one embodiment, each error correction protected block 224 includes 4 error correction symbols 408 (for the 251 data symbols 432) and 4 error correction symbols 440 (for the 251 data symbols 436).

The error correction protected blocks 224 are aggregated into a superblock 232, as shown in FIG. 4. In FIG. 4, the superblock 232 includes 4 error correction protected blocks 224 or 8 blocks of X/2-bit symbols. Four of the X/2-bit blocks include the lower X/2 bits and the remaining four of the X/2-bit blocks include the upper X/2 bits. In one embodiment, the superblock 232 includes 251×4=1004 16-bit data words.

The error correction protected blocks 224 are generated from the video data packets 216 and blanking data packets 217, as described above with reference to FIG. 2. The forward error correction encoder circuit 220 selects 251 16-bit data words from the video data packets 216. The 251 16-bit data words are split into 251 lower 8-bit data symbols 436 and 251 upper 8-bit data symbols 432. The forward error correction encoder circuit 220 performs forward error correction encoding on the 251 lower 8-bit data symbols 436 to generate 4 lower 8-bit error correction symbols 440. The forward error correction encoder circuit 220 performs forward error correction encoding on the 251 upper 8-bit data symbols 432 to generate 4 upper 8-bit error correction symbols 408. The 4 lower 8-bit error correction symbols 440 and 4 upper 8-bit error correction symbols 408 may be combined into 4 16-bit error correction words of an error corrected protected superblock 224, as illustrated in FIG. 4.

Each video data packet 216 and blanking data packet 217 includes an X-bit header 416 including a P-bit type symbol 424 and a Q-bit length symbol 428 shown in FIG. 4. In one embodiment, P equals 6 and Q equals 10. The header 416 precedes the payload words 420 and may contain addressing and other data. In one embodiment, the first word of a superblock 232 is the header 416 and the number of following payload words 420 is specified by the value of the Q-bit length symbol 428.

The type of data carried by the payload words 420 may be specified by the value of the P-bit type symbol 424, as shown in FIG. 4. For example a type of 0 may denote the payload data 420 is reserved. A type of 1 may denote the payload data 420 is gap data, meaning dummy data to be ignore by the sink device 300. A type of 2 may denote the payload data 420 is video data, meaning pixels in a defined sequence. A type of 3 may denote the payload data 420 is blanking data 208, meaning control periods and data islands. A type of 4-62 may denote the payload data 420 is reserved, meaning reserved for other future data streams. A type of 63 may denote the payload data 420 is reserved, meaning reserved for extension.

The forward error correction encoder circuit generates a single set of parity bits (e.g., error correction symbols 408) to protect both the header 416 and the payload 420 instead of generating separate sets of parity bits for the header 416 and the payload 420. The benefits and advantages of this approach are that it reduces hardware and data processing overhead and complexity since only a single set of parity bits is generated by the forward error correction encoder circuit 220 and analyzed by the error correction circuit 312 instead of two sets of parity bits. Error protection of the entire data stream in this manner obviates the addition of overhead to the headers. Redundancy in the header is no longer required to be able to search for the headers in an error-prone data stream. Because the entire data stream is protected, such redundancy is not needed. Therefore, bandwidth is increased.

The X-bit words of the error correction protected blocks 224 that are in the superblock 232 are encoded according to the encoding process illustrated and described in detail below with reference to FIG. 5.

### Word Encoding

FIG. 5 is a high-level block diagram of the encoding process 500, according to one embodiment. The X-bit words (including X/2-bit data symbols 432 and X/2-bit data symbols 436) of the error correction protected blocks 224 in a superblock 232 are encoded into Y-bit encoded words for transmission to the sink device 300 over one or more multimedia lanes of a multimedia communication link, where X is smaller than Y. In the embodiment illustrated in FIG. 5, X equals 16 and Y equals 18. The error correction symbols 408 are the parity check symbols for the data symbols 432, and the error correction symbols 440 are the parity check symbols for the data symbols 436. The example error correction protected blocks 224 shown in FIG. 5 includes 255 X-bit words.

The encoding of the X-bit words of superblock 232 into Y-bit encoded words is performed by partitioning each X-bit word into R lower bits (e.g. 7 bits) and U upper bits (e.g. 9 bits). The R lower bits of the X-bit word are encoded into S lower bits (encoded symbols 528) of the Y-bit encoded word using the process 520, where R is smaller than S. In one embodiment, R equals 7 and S equals 8. The U upper bits of the X-bit word are encoded into T upper bits (encoded symbols 524) of the Y-bit encoded word using the process 516. R is different than U, and U is smaller than T. In one embodiment, U equals 9 and T equals 10.

### Decoding of Encoded Words

FIG. 6 is a high-level block diagram of the decoding process 600, according to one embodiment. A multimedia block received by the decoder 304 includes 1004 Y-bit encoded words. The 1004 Y-bit words contain 4 blocks of 255 Y-bit encoded words. FIG. 6 illustrates one of these blocks of 255 Y-bit encoded words. The 255 Y-bit words of a multimedia block shown in FIG. 6 include 255 S-bit encoded symbols 528 and 255 T-bit encoded symbols 528 transmitted by the source device 200. In one embodiment, Y equals 18, S equals 8, and T equals 10. The decoding of the Y-bit encoded words into X-bit words is performed by decoding the S lower bits (encoded symbols 528) of the Y-bit encoded word into R lower bits of the X-bit word by the decoding process 620 shown in FIG. 6. In one embodiment, X equals 16 and R equals 7.

The T upper bits (encoded symbols 524) of the Y-bit encoded word are decoded into U upper bits of the X-bit word by the decoding process 616 shown in FIG. 6, wherein S is different than T and U is smaller than T. In one embodiment, T equals 10 and U equals 9. The U upper bits and R lower bits are combined into an X-bit word including X/2 upper bits (data symbols 432 and error correction symbols 408) and X/2 lower bits (data symbols 436 and error correction symbols 440). In one embodiment X/2 equals 8.

In one embodiment, in which the sink device 300 includes decision feedback equalization (DFE) circuitry, a single bit error 624 in the encoded symbols 524 may manifest, after decoding 600, as a multi-bit error 628 in the U upper bits of the X bit word in the 255 word error correction protected block 224, where each word has X bits. A single bit error 632 in the encoded symbols 528 will manifest, after decoding 600, as a multi-bit error 636 in the R lower bits of the X bit word in the 255 word error correction protected block 224. The error correction circuit 312 can correct any 2 errors per 255 18-bit encoded words, and can correct 3 errors or 4 errors per 255 18-bit encoded words in some situations. Therefore, the benefits and advantages of the disclosed decoding embodiments 600 are reduced single-point-failure issues, reduced probability of a next bit error after an error, and reduced probability of uncorrectable burst. In one embodiment, in which the sink device 300 includes decision feedback equalization (DFE) circuitry, the error correction circuit 312 has tolerance to error multiplication because Reed-Solomon encoding is used instead of BCH encoding. This is because Reed-Solomon encoding can correct data transmissions in which one bit of a codeword is faulty as well as when an entire encoded word is faulty. In the latter case, the error correction circuit 312 is able to replace the entire faulty word during the correction process.

### Encoded Superblock

FIG. 7 is an illustration of an encoded superblock 704 of Y-bit words 712 and the symbol decoding process 700, according to one embodiment. In the embodiment illustrated in FIG. 7, the encoded superblock 704 includes 4 blocks of 255 words 712 of 18 bits each. Each word 712 of 18 bits is received across one of the 4 multimedia lanes 240 through 252. A block start word 708, labeled as “BS” in FIG. 7, indicating a start of the superblock 704 across the multimedia lanes 240 through 252 of the multimedia communication link, is received before the Y-bit encoded words 712 of the superblock 704 are received across the multimedia lanes. The block start word 708 is a unique Y-bit word that does not have a corresponding X-bit word (i.e., the Y-bit word 708 marking the start of the superblock 704 is an “out of band” symbol.) The encoded words 712 of an encoded superblock 704 may be distributed in an interleaving pattern across the multimedia lanes 240 through 252 as shown in FIG. 7. In other words, the distribution of encoded words 712 across the multimedia lanes may be different than that shown in FIG. 7.

The Y-bit encoded words, transmitted from the source device 200 over the multimedia lanes 240 through 252, are decoded into X-bit words of error correction protected blocks 224 in a superblock, where X is smaller than Y. In one embodiment, X equals 16. The superblock is disaggregated into 4 error correction protected blocks 224. Each error correction protected block 224 includes X-bit data words and X-bit error correction words. Each error correction protected block 224 includes X/2-bit data symbols 436 and X/2-bit error correction symbols 440 that are parity check bits for the data symbols 436. Each error correction protected block 224 also includes X/2-bit data symbols 432 and X/2-bit error correction symbols 408 that are parity check bits for the data symbols 436.

Video data packets 216, blanking data packets 217, as well as gap data packets may be generated from the error correction protected blocks 224. In one embodiment, the video data packets 216 are generated by a Reed-Solomon error correction decoder 312. The video data packets 216 are depacketized into video data 204.

In one embodiment, the encoding process at the source device 200 is the reverse of the decoding process explained by references to FIG. 7.

### Process of Video Data Encoding

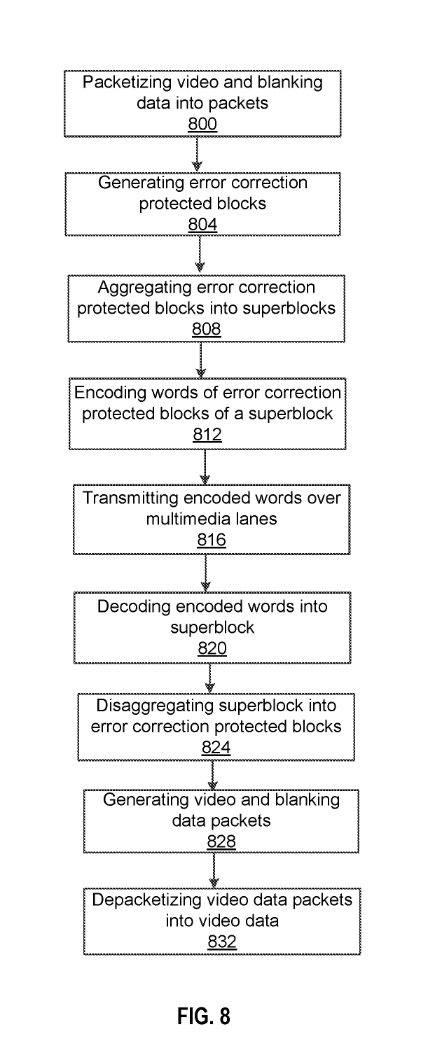

FIG. 8 is a flow chart illustrating the operation of the source device 200, according to one embodiment. In some embodiments, the process may have different and/or additional steps than those described in conjunction with FIG. 8. Steps of the process may be performed in different orders than the order described in conjunction with FIG. 8. Some steps may be executed in parallel. Alternatively, some of the steps may be executed in parallel and some steps executed sequentially. Alternatively, some steps may execute in a pipelined fashion such that execution of a step is started before the execution of a previous step.

The packetizer 212 packetizes 800 the video data 204 and blanking data 208 into the video data packets 216 and blanking data packets 217. Each video data packet 216 and blanking data packet 217 includes an X-bit header including a P-bit type symbol and a Q-bit length symbol, as described and illustrated above in detail with reference to FIG. 4. In one embodiment, X equals 16, P equals 6, and Q equals 10. The forward error correction encoder circuit 220 generates 804 error correction protected blocks 224 from the video data packets 216. Each error correction protected block 224 includes data words and error correction words.

The superblock aggregator circuit 228 aggregates 808 the error correction protected blocks 224 into a superblock 232. The encoder circuit 236 encodes 812 X-bit words of the error correction protected blocks 224 that are in the superblock 232 into Y-bit encoded words for transmission 816 to the sink device 300 over one or more multimedia lanes 240 through 252 of a multimedia communication link, where X is smaller than Y. In one embodiment, X equals 16 and Y equals 18. A block start word indicating a start of the superblock 232 may be transmitted across the multimedia lanes 240 through 252 of the multimedia link before the Y-bit encoded words of the superblock are transmitted 816 across the multimedia lanes 240 through 252.

The decoder circuit 304 decodes 820 the Y-bit words into X-bit words of error correction protected blocks 224 (in a superblock 232), where X is smaller than Y. In an embodiment, X may be 16 and Y may be 18 such that the decoder 304 implements 18b16b decoding. The superblock disaggregator circuit 308 disaggregates 824 a superblock 232 into a plurality of the error correction protected blocks 224. The error correction circuit 312 generates 828 video data packets 216 and blanking data packets 217 from the error correction protected blocks 224. The depacketizer circuit 316 depacketizes 832 the video data packets 216 into video data 204.

The benefits and advantages of the disclosed embodiments are reduced hardware overhead because of the use of a single set of parity check bits for both header and payload words. By performing forward error correction encoding before performing 16b18b encoding, the hardware of the source device can be simplified, and the sink device can also be simplified. Moreover, improved bandwidth utilization is achieved. The data packets include only a single header word, which reduces overhead in the data stream. Combining the error correction protected blocks 224 into a superblock reduces the frequency of the block start words, i.e., fewer block start words 708 need to be transmitted overall since block start words 708 will only be transmitted once every superblock 232 is transmitted and not once every correction protected block 224 is transmitted. This increases efficiency of transmission and reduces wasted data transmission. Since the entire datastream, including video data and blanking data, is protected with parity, single-point-failure is reduced and lossless transmission is achieved.

Upon reading this disclosure, those of skill in the art will appreciate still additional alternative embodiments for forward error correction and asymmetric encoding for video data transmission for a multimedia interface. Thus, while particular embodiments and applications of the present disclosure have been illustrated and described, it is to be understood that the embodiments are not limited to the precise construction and components disclosed herein and that various modifications, changes and variations which will be apparent to those skilled in the art may be made in the arrangement, operation and details of the method and apparatus of the present disclosure disclosed herein without departing from the spirit and scope of the disclosure as defined in the appended claims.

What is claimed is:

1. A source device, comprising:
a forward error correction encoder circuit to generate error correction protected blocks from video data packets, each error correction protected block comprising data words and error correction words; and
an encoder circuit to encode X-bit words of the error correction protected blocks into Y-bit encoded words for transmission to a sink device over one or more multimedia lanes of a multimedia communication link, where X is smaller than Y.

2. The source device of claim 1, further comprising a packetizer circuit to packetize video data into the video data packets, each video data packet comprising an X-bit header comprising a P-bit type symbol and a Q-bit length symbol.

3. The source device of claim 2, wherein:
the forward error correction encoder circuit generates the error correction protected blocks from the video data packets and blanking data packets; and
the packetizer circuit packetizes blanking data into the blanking data packets.

4. The source device of claim 1, wherein the forward error correction encoder circuit is a Reed-Solomon forward error correction encoder.

5. The source device of claim 1, further comprising a superblock aggregator circuit to:
aggregate a plurality of the error correction protected blocks into a superblock, wherein the encoder circuit encodes the X-bit words of the error correction protected blocks that are in the superblock,
wherein a block start word indicating a start of the superblock is transmitted across each of the multimedia lanes of the multimedia link before the Y-bit encoded words of the superblock are transmitted across the multimedia lanes.

6. The source device of claim 1, wherein the data words of each error correction protected block each include X/2 upper bits and X/2 lower bits, the error correction words each include X/2 upper bits that are parity check bits for the X/2 upper bits of the data words, and the error correction words each include X/2 lower bits that that are parity check bits for the X/2 lower bits of the data words.

7. The source device of claim 6, wherein the encoder circuit encodes an X-bit word of the error correction protected block into a Y-bit encoded word by:
encoding R lower bits of the X-bit word into S lower bits of the Y-bit encoded word; and
encoding U upper bits of the X-bit word into T upper bits of the Y-bit encoded word, wherein R is different than U, R is smaller than S, and U is smaller than T.

8. A sink device, comprising:
a decoder circuit to decode Y-bit encoded words, received from a source device over one or more multimedia lanes of a multimedia communication link, into X-bit words of error correction protected blocks, where X is smaller than Y; and
an error correction circuit to generate video data packets from the error correction protected blocks, each error correction protected block comprising data words and error correction words.

9. The sink device of claim 8, further comprising a depacketizer circuit to depacketize the video data packets into video data, each video data packet comprising an X-bit header comprising a P-bit type symbol and a Q-bit length symbol.

10. The sink device of claim 9, wherein:
the error correction circuit generates blanking data packets from the error correction protected blocks; and
the depacketizer circuit depacketizes the blanking data packets into blanking data.

11. The sink device of claim 8, wherein the error correction circuit is a Reed-Solomon error correction decoder.

12. The sink device of claim 8, wherein the X-bit words are organized into a superblock and the start of a superblock is indicated by block start words received across each of the multimedia lanes of the multimedia communication link, and the sink device further comprises a superblock disaggregator circuit to:
disaggregate the superblock into a plurality of the error correction protected blocks.

13. The sink device of claim 8, wherein the decoder circuit decodes a Y-bit encoded word into an X-bit word of the error correction protected block by:
decoding S lower bits of the Y-bit encoded word into R lower bits of the X-bit word; and
decoding T upper bits of the Y-bit encoded word into U upper bits of the X-bit word, wherein S is different than T, R is smaller than S, and U is smaller than T.

14. The sink device of claim 13, wherein the data words of each error correction protected block each include X/2 upper bits and X/2 lower bits, the error correction words each include X/2 upper bits that are parity check bits for the X/2 upper bits of the data words, and the error correction words each include X/2 lower bits that that are parity check bits for the X/2 lower bits of the data words.

15. A method, comprising:
generating error correction protected blocks from video data packets, each error correction protected block comprising data words and error correction words; and
encoding X-bit words of the error correction protected blocks into Y-bit encoded words for transmission to a sink device over one or more multimedia lanes of a multimedia communication link, where X is smaller than Y.

16. The method of claim 15, further comprising packetizing video data into the video data packets, each video data packet comprising an X-bit header comprising a P-bit type symbol and a Q-bit length symbol.

17. The method of claim 15, wherein the error correction protected blocks are generated using Reed-Solomon encoding.

18. The method of claim 15, further comprising:
aggregating a plurality of the error correction protected blocks into a superblock, wherein the encoding is of the X-bit words of the error correction protected blocks that are in the superblock; and
transmitting a block start word indicating a start of the superblock across the multimedia lanes of the multimedia link before the Y-bit encoded words of the superblock are transmitted across the multimedia lanes.

19. The method of claim 15, wherein the data words of each error correction protected block each include X/2 upper bits and X/2 lower bits, the error correction words each include X/2 upper bits that are parity check bits for the X/2 upper bits of the data words, and the error correction words each include X/2 lower bits that that are parity check bits for the X/2 lower bits of the data words.

20. The method of claim 19, wherein the encoding of the X-bit words into Y-bit encoded words comprises:
encoding R lower bits of the X-bit word into S lower bits of the Y-bit encoded word; and
encoding U upper bits of the X-bit word into T upper bits of the Y-bit encoded word, wherein R is different than U, R is smaller than S, and U is smaller than T.

21. A method, comprising:
decoding Y-bit encoded words, transmitted from a source device over one or more multimedia lanes of a multimedia communication link, into X-bit words of error correction protected blocks, where X is smaller than Y; and
generating video data packets from the error correction protected blocks, each error correction protected block comprising data words and error correction words.

22. The method of claim 21, further comprising depacketizing the video data packets into video data, each data packet comprising an X-bit header comprising a P-bit type symbol and a Q-bit length symbol.

23. The method of claim 21, wherein the video data packets are generated from the error protected blocks using Reed-Solomon decoding.

24. The method of claim 21, wherein the X-bit words are organized into a superblock and the start of a superblock is indicated by block start words received across each of the multimedia lanes of the multimedia communication link, wherein the method further comprises:
disaggregating the superblock into a plurality of the error correction protected blocks.

25. The method of claim 21, wherein the decoding of the Y-bit encoded words into X-bit words comprises:
decoding S lower bits of the Y-bit encoded word into R lower bits of the X-bit word; and
decoding T upper bits of the Y-bit encoded word into U upper bits of the X-bit word, wherein S is different than T, R is smaller than S, and U is smaller than T.

26. The method of claim 25, wherein the data words of each error correction protected block each include X/2 upper bits and X/2 lower bits, the error correction words each include X/2 upper bits that are parity check bits for the X/2 upper bits of the data words, and the error correction words each include X/2 lower bits that that are parity check bits for the X/2 lower bits of the data words.
